(19) United States
(12) Patent Application Publication
(10) Pub. No.: US 2017/0125241 A1
(43) Pub. Date: May 4, 2017

(54) LOW TEMP SINGLE PRECURSOR ARC HARD MASK FOR MULTILAYER PATTERNING APPLICATION

(71) Applicant: Applied Materials, Inc., Santa Clara, CA (US)

(72) Inventors: Shaunak MUKHERJEE, Santa Clara, CA (US); Kang Sub YIM, Palo Alto, CA (US); Deenesh PADHI, Sunnyvale, CA (US); Kevin M. CHO, Fremont, CA (US); Khoi Anh PHAN, San Jose, CA (US); Chien-An CHEN, San Jose, CA (US); Priyanka DASH, Menlo Park, CA (US)

(21) Appl. No.: 15/074,038

(22) Filed: Mar. 18, 2016

Related U.S. Application Data
(60) Provisional application No. 62/248,877, filed on Oct. 30, 2015.

(51) Int. Cl. H01L 21/02; H01L 21/32

(52) U.S. Cl. CPC H01L 21/02164; H01L 21/02214; H01L 21/02211; H01L 21/02274; H01L 21/32

(57) ABSTRACT

Methods of single precursor deposition of hardmask and ARC layers, are described. The resultant film is a SiOC layer with higher carbon content terminated with high density silicon oxide SiO₂ layer with low carbon content. The method can include delivering a first deposition precursor to a substrate, the first deposition precursor comprising an SiOC precursor and a first flow rate of an oxygen containing gas; activating the deposition species using a plasma, whereby a SiOC containing layer over an exposed surface of the substrate is deposited. Then delivering a second precursor gas to the SiOC containing layer, the second deposition gas comprising different or same SiOC precursor with a second flow rate and a second flow rate of the oxygen containing gas and activating the deposition gas using a plasma, the second deposition gas forming a SiO₂ containing layer over the hardmask, the SiO₂ containing layer having very low carbon.

### CROSS-REFERENCE TO RELATED APPLICATIONS

This application claims priority to U.S. Provisional Patent Application Ser. No. 62/248,877, filed on Oct. 30, 2015, which is incorporated by reference herein.

### BACKGROUND

Field

Implementations of the present disclosure generally relate to deposition of device formation layers in semiconductor device formation.

Description of the Related Art

One of the numerous steps involved in the fabrication of modern semiconductor devices is the deposition of hardmask films. Hardmask films can be deposited on a substrate by chemical vapor deposition. Hard mask materials have been evolving to enhance resolution and provide the robustness necessary to enable advanced multilayer patterning. Advanced multilayer patterning includes selectivity to etch and ashing chemistries, improved profile control, and critical diameter uniformity.

A hardmask is conventionally used to protect device structures during processing. The hardmask is etched at a much lower rate than any material contained in the underlying layer. The hardmask, therefore, allows the underlying layer to be processed without excessive thicknesses of photoresist. Typically, the hardmask is deposited using chemical vapor deposition (“CVD”). An anti-reflective coating (“ARC”) is then deposited over the hardmask. The ARC is generally deposited using a spin-on process, in a second chamber. Finally, the photoresist is deposited over the ARC such that the hardmask can be patterned and the underlying layer can be etched.

However, deposition in multiple chambers has a variety of deficiencies. First and foremost, separate chemistries are used to deposit the etch hardmask and the ARC, adding to the cost of the deposited layers. Further, multiple chambers are used for the separate depositions, which increases production time and cost. As well, the second chamber uses platform space that could otherwise be dedicated to another processing step.

Accordingly, what is needed in the art is a hardmask and ARC that addresses the above limitations.

### SUMMARY

Implementations disclosed herein include methods of forming a SiOC film followed by a terminating SiO₂ cap layer for use in semiconductor device formation. In one implementation, a method of forming a layer can include first delivering a SiOC precursor comprising of Silicon, Carbon and Oxygen to a substrate in a process chamber. The SiOC precursor can be flown at a first flow rate along with an oxygen containing gas which can be flown at a second flow rate, to create a deposition gas mixture. The second flow rate can be greater than the first flow rate. The deposition gas mixture is activated using plasma, such as RF plasma. The deposition gas mixture forms a SiOC containing layer over an exposed surface of the substrate. Following deposition of the SiOC containing layer, a SiO₂ oxide cap layer can then be deposited. The SiO₂ oxide cap layer can be deposited in situ from the same precursors that deposited the SiOC containing layer.

To form the SiO₂ oxide cap layer, a second deposition gas mixture is then delivered to the process chamber. The second deposition gas mixture can comprise the same or a second SiOC precursor and the same or a second oxygen containing gas. The second SiOC precursor can be the same as the first SiOC precursor. The second oxygen containing gas can be the same as the first oxygen containing gas but flown at a second flow rate higher than the flow rate of the first oxygen containing gas. The second deposition gas mixture can be activated using plasma, and the second deposition gas can form a SiO₂ containing layer over the hardmask. The SiOC containing layer contains carbon to have a dielectric constant less than 3.0, whereas the SiO₂ cap layer has low carbon content for a dielectric constant above 3.5.

In another implementation, a method of forming a layer can include delivering a first SiOC precursor to a substrate positioned in the processing region of a process chamber; forming a plasma using a first oxygen-containing gas creating a first activated oxygen precursor, the first oxygen containing gas being delivered at a carbon preserving flow rate; delivering the first activated oxygen precursor to the first SiOC precursor, the first activated oxygen precursor reacting with the first SiOC precursor to deposit a hardmask on the exposed surface of the substrate; delivering a second SiOC precursor to the substrate; forming a plasma using a second oxygen-containing precursor creating a second activated oxygen precursor, the second activated oxygen precursor being delivered at a carbon depleting flow rate; and delivering the second activated oxygen precursor to the second SiOC precursor, the second activated oxygen precursor reacting with the second SiOC precursor to deposit an anti-reflective coating on the hardmask, the anti-reflective coating having the low carbon content.

In another implementation, a method of forming a layer can include delivering an SiOC precursor to a substrate, the SiOC precursor comprising diethoxymethylsilane or bis(triethoxysilyl)methane, when the substrate is positioned in the processing region of a process chamber at a flow rate of 200 mgm to 1000 mgm. A plasma can then be formed in the presence of an O₂ and Helium gas. The O₂ gas can be delivered at a flow rate of between 25 sccm and 800 sccm to the process chamber. Inside the process chamber, O₂ reacts with the SiOC precursor and deposits a silicon oxycarbide (SiOC) hardmask on the exposed surface of the substrate prior to depositing the silicon oxide layer.

### BRIEF DESCRIPTION OF THE DRAWINGS

So that the manner in which the above recited features of the present disclosure can be understood in detail, a more particular description of the disclosure, briefly summarized above, may be had by reference to implementations, some of which are illustrated in the appended drawings. It is to be noted, however, that the appended drawings illustrate only typical implementations of this disclosure and are therefore not to be considered limiting of its scope, for the disclosure may admit to other equally effective implementations.

FIG. 1 depicts a process chamber capable of performing the methods described herein.

FIG. 2 depicts a second process chamber capable of performing the methods described herein.

FIGS. 3A and 3B depict platforms capable of performing the methods described herein.

FIG. 4 is a block diagram of a method of forming the hardmask and ARC layers, according to one implementation.

FIGS. 5A-5E depict a substrate having one or more layers deposited using implementations of methods described herein.

To facilitate understanding, identical reference numerals have been used, wherever possible, to designate identical elements that are common to the Figures. Additionally, elements of one implementation may be advantageously adapted for utilization in other implementations described herein.

### DETAILED DESCRIPTION

Implementations disclosed herein include a chemical vapor deposition technique to fabricate low temperature (temperatures less than or equal to 225 degrees Celsius), conformal carbon doped silicon oxide (SiOC) film. Methods described herein disclose the use of a single precursor for the formation of a nitrogen-free anti-reflective coating (ARC) as well as a hardmask using the SiOC film. The ARC and hardmasks described herein can be used in semiconductor patterning, such as in BEOL semiconductor patterning application.

Carbon content of the deposited SiOC film can be modulated by changes in deposition process parameters. The carbon concentration of SiOC film is a linear function of mask opening etch rate under fluorocarbon plasma chemistry, whereas the terminating SiO₂ oxide will enable ashing resistance of the hard mask under Oxygen radical ash chemistries used for rework. A combination of low cost, high deposition rate single precursor films along with high etch and low rework ash loss provides numerous benefits for use of this SiOC film for hardmask applications. On the other hand, the n and k tunability at 193 nm of the SiOC film provide numerous advantages as a replacement for conventional SiARC film in the conventional tri-layer dielectric stack. Implementations are more clearly described with reference to the figures below.

As used herein, “substantially free of carbon” or “substantially carbon free” means carbon is present in amounts insufficient to reduce k value by more than 0.1. “Low frequency radio frequency” refers to frequencies in the kilohertz (kHz) range, such as between 30 kHZ and 300 kHz. “High frequency radio frequency” refers to radio frequencies above the “low frequency radio frequency” range.

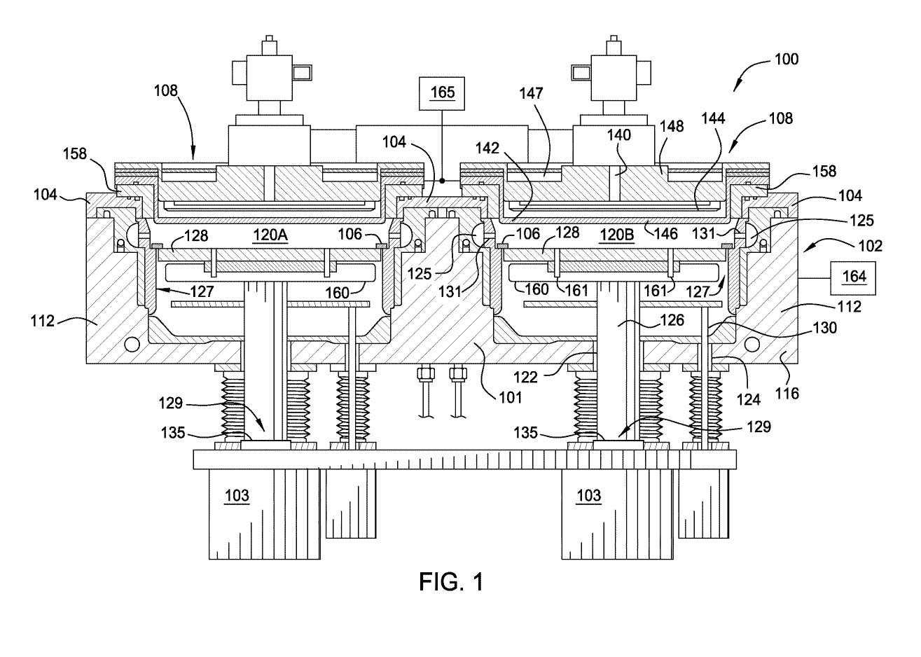

FIG. 1 is a partial cross sectional view of an exemplary plasma system 100 which may be used or modified to perform the methods described herein. The plasma system 100 generally comprises a processing chamber body 102 having sidewalls 112, a bottom wall 116 and an interior sidewall 101 defining a pair of processing regions 120A and 120B. Each of the processing regions 120A-B is similarly configured, and for the sake of brevity, only components in the processing region 120B are described.

A pedestal 128 is disposed in the processing region 120B through a passage 122 formed in the bottom wall 116 in the system 100. The pedestal 128 is adapted to support a substrate (not shown) on the upper surface thereof. The pedestal 128 may include heating elements, for example resistive elements, to heat and control the substrate temperature at a desired process temperature. Alternatively, the pedestal 128 may be heated by a remote heating element, such as a lamp assembly.

The pedestal 128 is coupled by a shaft 126 to a power outlet or power box 103, which may include a drive system that controls the elevation and movement of the pedestal 128 within the processing region 120B. The shaft 126 also contains electrical power interfaces to provide electrical power to the pedestal 128. The power box 103 also includes interfaces for electrical power and temperature indicators, such as a thermocouple interface. The shaft 126 also includes a base assembly 129 adapted to detachably couple to the power box 103. A circumferential ring 135 is shown above the power box 103. In one implementation, the circumferential ring 135 is a shoulder adapted as a mechanical stop or land configured to provide a mechanical interface between the base assembly 129 and the upper surface of the power box 103.

A rod 130 is disposed through a passage 124 formed in the bottom wall 116 and is utilized to activate substrate lift pins 161 disposed through the pedestal 128. The substrate lift pins 161 selectively space the substrate from the pedestal to facilitate exchange of the substrate with a robot (not shown) utilized for transferring the substrate into and out of the processing region 120B through a substrate transfer port 160.

A chamber lid 104 is coupled to a top portion of the chamber body 102. The lid 104 accommodates one or more gas distribution systems 108 coupled thereto. The gas distribution system 108 includes a gas inlet passage 140 which delivers reactant and cleaning gases through a showerhead assembly 142 into the processing region 120B. The showerhead assembly 142 includes an annular base plate 148 having a blocker plate 144 disposed intermediate to a faceplate 146. A radio frequency (RF) source 165 is coupled to the showerhead assembly 142. The RF source 165 powers the showerhead assembly 142 to facilitate generation of plasma between the faceplate 146 of the showerhead assembly 142 and the heated pedestal 128. In one implementation, the RF source 165 may be a high frequency radio frequency (HFRF) power source, such as a 13.56 MHz RF generator. In another implementation, RF source 165 may include a HFRF power source and a low frequency radio frequency (LFRF) power source, such as a 300 kHz RF generator. Alternatively, the RF source may be coupled to other portions of the processing chamber body 102, such as the pedestal 128, to facilitate plasma generation. A dielectric isolator 158 is disposed between the lid 104 and showerhead assembly 142 to prevent conducting RF power to the lid 104. A shadow ring 106 may be disposed on the periphery of the pedestal 128 that engages the substrate at a desired elevation of the pedestal 128.

Optionally, a cooling channel 147 is formed in the annular base plate 148 of the gas distribution system 108 to cool the annular base plate 148 during operation. A heat transfer fluid, such as water, ethylene glycol, a gas, or the like, may be circulated through the cooling channel 147 such that the base plate 148 is maintained at a predefined temperature.

A chamber liner assembly 127 is disposed within the processing region 120B in very close proximity to the sidewalls 101, 112 of the chamber body 102 to prevent exposure of the sidewalls 101, 112 to the processing environment within the processing region 120B. The liner assembly 127 includes a circumferential pumping cavity 125 that is coupled to a pumping system 164 configured to exhaust gases and byproducts from the processing region 120B and control the pressure within the processing region 120B. A plurality of exhaust ports 131 may be formed on the chamber liner assembly 127. The exhaust ports 131 are configured to allow the flow of gases from the processing region 120B to the circumferential pumping cavity 125 in a manner that promotes processing within the system 100.

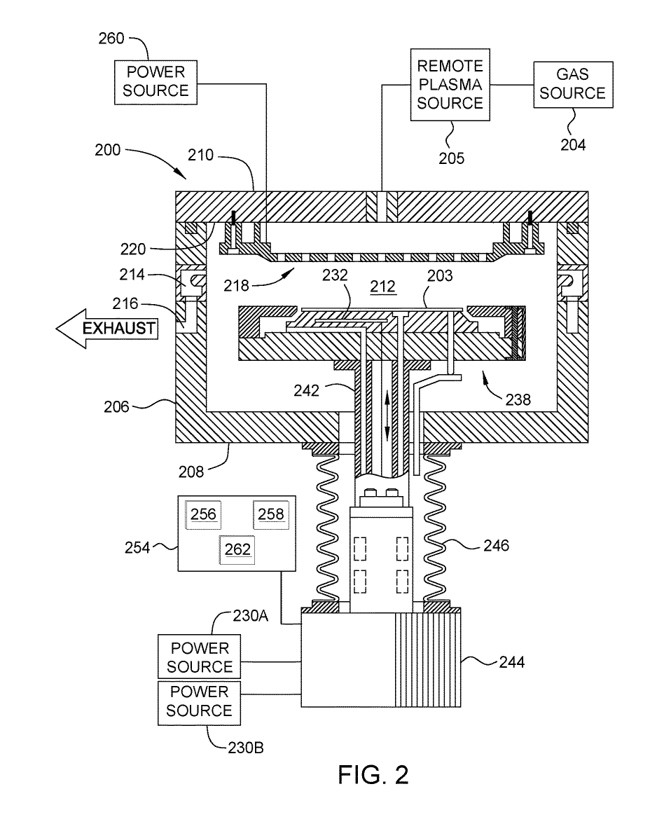

FIG. 2 is a schematic cross-sectional view of a CVD process chamber 200 that may be used for depositing a hardmask layer or an ARC layer according to the implementations described herein. A process chamber that may be adapted to perform the layer deposition methods described herein is the PRECISION® chemical vapor deposition chamber, available from Applied Materials, Inc. located in Santa Clara, Calif. It is to be understood that the chamber described below is an exemplary implementation and other chambers, including chambers from other manufacturers, may be used with or modified to match implementations described herein without diverging from the characteristics of implementations described herein.

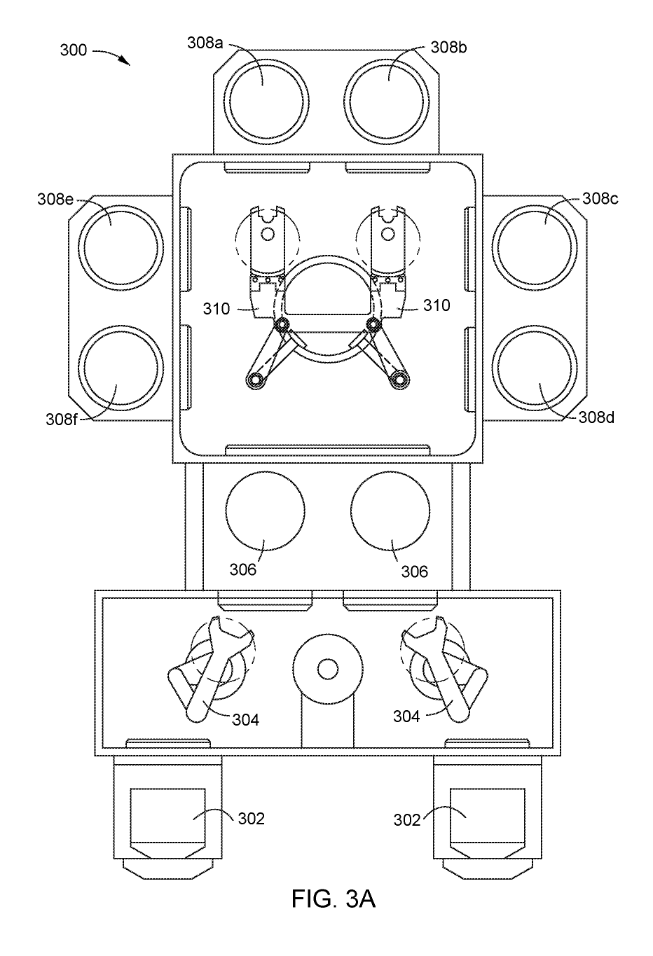

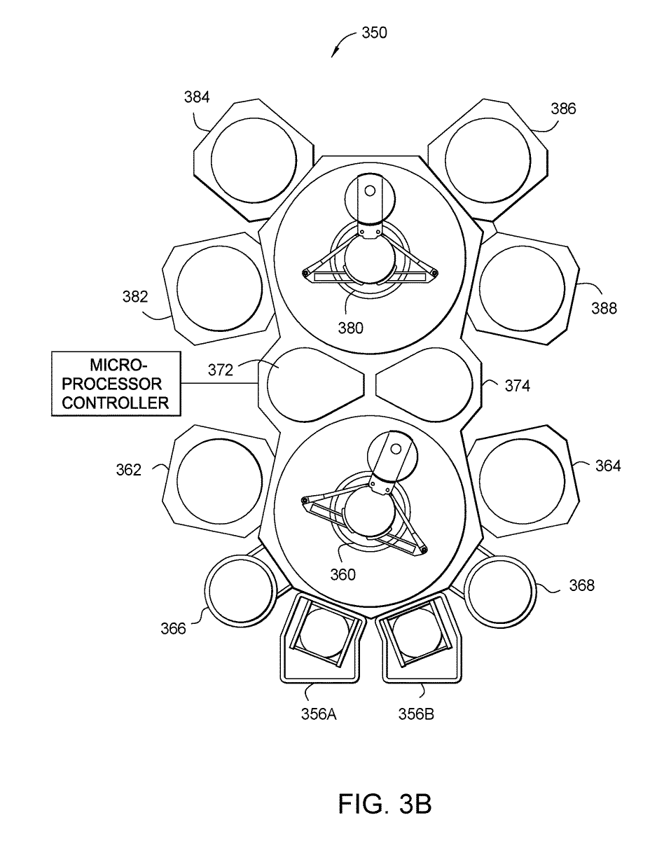

The process chamber 200 may be part of a processing system that includes multiple process chambers connected to a central transfer chamber and serviced by a robot. In one implementation, the processing system is the platform 300, described in FIG. 3. The process chamber 200 includes walls 206, a bottom 208, and a lid 210 that define a process volume 212. The walls 206 and bottom 208 can be fabricated from a unitary block of aluminum. The process chamber 200 may also include a pumping ring 214 that fluidly couples the process volume 212 to an exhaust port 216 as well as other pumping components (not shown).

A substrate support assembly 238, which may be heated, may be centrally disposed within the process chamber 200. The substrate support assembly 238 supports a substrate 203 during a deposition process. The substrate support assembly 238 generally is fabricated from aluminum, ceramic or a combination of aluminum and ceramic, and includes at least one bias electrode 232. The bias electrode 232 may be an e-chuck electrode, an RF substrate bias electrode or combinations thereof.

A vacuum port may be used to apply a vacuum between the substrate 203 and the substrate support assembly 238 to secure the substrate 203 to the substrate support assembly 238 during the deposition process. The bias electrode 232 may be, for example, the electrode 232 disposed in the substrate support assembly 238, and coupled to a bias power source 230A and 230B, to bias the substrate support assembly 238 and substrate 203 positioned thereon to a predetermined bias power level while processing.

The bias power source 230A and 230B can be independently configured to deliver power to the substrate 203 and the substrate support assembly 238 at a variety of frequencies, such as a frequency between about 2 MHz and about 60 MHz. Various permutations of the frequencies described here can be employed without diverging from the implementation described herein.

Generally, the substrate support assembly 238 is coupled to a stem 242. The stem 242 provides a conduit for electrical leads, vacuum and gas supply lines between the substrate support assembly 238 and other components of the process chamber 200. Additionally, the stem 242 couples the substrate support assembly 238 to a lift system 244 that moves the substrate support assembly 238 between an elevated position (as shown in FIG. 2) and a lowered position (not shown) to facilitate robotic transfer. Bellows 246 provides a vacuum seal between the process volume 212 and the atmosphere outside the chamber 200 while facilitating the movement of the substrate support assembly 238.

The showerhead 218 may generally be coupled to an interior side 220 of the lid 210. Gases (i.e., process gases and/or other gases) that enter the process chamber 200 pass through the showerhead 218 and into the process chamber 200. The showerhead 218 may be configured to provide a uniform flow of gases to the process chamber 200. Uniform gas flow is desirable to promote uniform layer formation on the substrate 203. A remote plasma source 205 can be coupled between a gas source 204 and the process volume 212. Shown here, a remote activation source, such as a remote plasma generator, is used to generate a plasma of reactive species which are then delivered into the process volume 212. Exemplary remote plasma generators are available from vendors such as MKS Instruments, Inc. and Advanced Energy Industries, Inc.

Additionally or in the alternative, a plasma power source 260 may be coupled to the showerhead 218 to energize the gases through the showerhead 218 towards substrate 203 disposed on the substrate support assembly 238. The plasma power source 260 may provide power for the formation of a plasma region, such as RF power or microwave power.

The function of the process chamber 200 can be controlled by a computing device 254. The computing device 254 may be one of any form of general purpose computer that can be used in an industrial setting for controlling various chambers and sub-processors. The computing device 254 includes a computer processor 256. The computing device 254 includes memory 258. The memory 258 may include any suitable memory, such as random access memory, read only memory, flash memory, hard disk, or any other form of digital storage, local or remote. The computing device 254 may include various support circuits 262, which may be coupled to the computer processor 256 for supporting the computer processor 256 in a conventional manner. Software routines, as required, may be stored in the memory 258 or executed by a second computing device (not shown) that is remotely located.

The computing device 254 may further include one or more computer readable media (not shown). Computer readable media generally includes any device, located either locally or remotely, which is capable of storing information that is retrievable by a computing device. Examples of computer readable media useable with implementations described herein include solid state memory, floppy disks, internal or external hard drives, and optical memory (e.g., CDs, DVDs, BR-D, etc). In one implementation, the memory 258 may be the computer readable media. Software routines may be stored on the computer readable media to be executed by the computing device.

The software routines, when executed, transform the general purpose computer into a specific process computer that controls the chamber operation so that a chamber process is performed. Alternatively, the software routines may be performed in hardware as an application specific integrated circuit or other type of hardware implementation, or a combination of software and hardware.

The exemplary process chamber 200 may be part of a platform. FIGS. 3A and 3B illustrate exemplary platform 300 and exemplary platform 350, respectively. Each of platform 300 and platform 350 are suitable for creating a nanocrystalline diamond layer on a substrate. The platforms 300 and 350 feature the process chamber 100 or the process chamber 200, as described above. An example of the platform 300 is the Producer® system available from Applied Materials, Inc., of Santa Clara, Calif. An example of the platform 350 is the Endura® system available from Applied Materials, Inc., of Santa Clara, Calif. Other platforms, including platforms manufactured by others, may be used as well.

FIG. 3 shows platform 300 of deposition, baking, and curing chambers. In the figure, a pair of FOUPs (front opening unified pods) 302 supply, substrates (e.g., 300 mm diameter wafers) that are received by robotic arms 304 and placed into a low pressure holding area 306 before being placed into one of the wafer processing chambers 308a-308f. A second robotic arm 310 may be used to transport the substrate wafers from the holding area 306 to the processing chambers 308a-308f and back.

The processing chambers 308a-308f may include one or more system components for depositing, annealing, curing, and/or etching a layer on the substrate. The layer or layers can be an SiOC layer or an SiO₂ layer. The layer or layers can be deposited by methods described herein. In one configuration, two pairs of the processing chamber (e.g., 308c and 308d and 308e and 308f) may be used to deposit the layer on the substrate, and the third pair of processing chambers (e.g., 308a and 308b) may be used to etch or anneal the deposited layer. In another configuration, the same two pairs of processing chambers (e.g., pair 308c and 308d and pair 308e and 308f) may be configured to both deposit a layer on the substrate, while the third pair of chambers (e.g., 308a and 308b) may be used for etching of the deposited layer. In still another configuration, all three pairs of chambers (e.g., 308a-308f) may be configured to deposit one or more layers on the substrate. In yet another configuration, two pairs of processing chambers (e.g., pair 308c and 308d and pair 308e and 308f) may be used for both deposition and etching of the layer, while a third pair of processing chambers (e.g., 308a and 308b) may be used for secondary processing of the layer or for deposition of a second layer. Any one or more of the processes described may be carried out on chamber(s) separated from the fabrication system shown in different embodiments.

The platform 350 can include one or more load lock chambers 356A, 356B for transferring of substrates into and out of the platform 350. Typically, since the platform 350 is under vacuum, the load lock chambers 356A, 356B may “pump down” the substrates introduced into the platform 350. A first robot 360 may transfer the substrates between the load lock chambers 356A, 356B, and a first set of one or more substrate process chambers 362, 364, 366, 368 (four are shown). Each process chamber 362, 364, 366, 368, can be outfitted to perform a number of substrate processing operations including the etch processes described herein in addition to cyclical layer deposition (CLD), atomic layer deposition (ALD), chemical vapor deposition (CVD), such as process chamber 200, pre-clean, degas, orientation and other substrate processes.

The first robot 360 can also transfer substrates between one or more intermediate transfer chambers 372, 374. The intermediate transfer chambers 372, 374 can be used to maintain ultrahigh vacuum conditions while allowing substrates to be transferred within the platform 350. A second robot 380 can transfer the substrates between the intermediate transfer chambers 372, 374 and a second set of one or more process chambers 382, 384, 386, 388. Similar to process chambers 362, 364, 366, 368, the process chambers 382, 384, 386, 388 can be outfitted to perform a variety of substrate processing operations including the etch processes described herein in addition to cyclical layer deposition (CLD), atomic layer deposition (ALD), chemical vapor deposition (CVD), physical vapor deposition (PVD), pre-clean, thermal process/degas, and orientation, for example. Any of the substrate process chambers 362, 364, 366, 368, 382, 384, 386, 388 may be removed from the platform 350 if not necessary for a particular process to be performed by the platform 350.

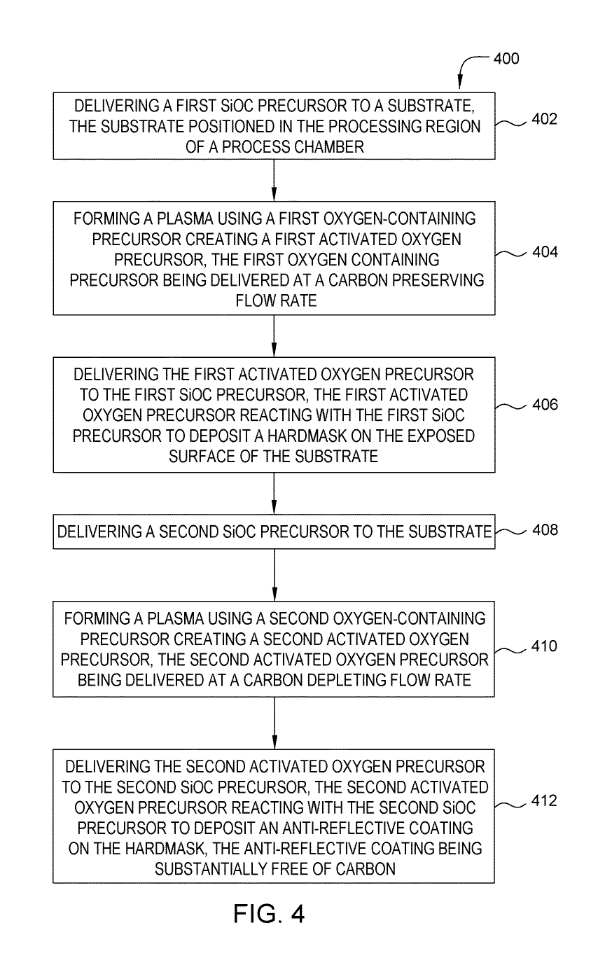

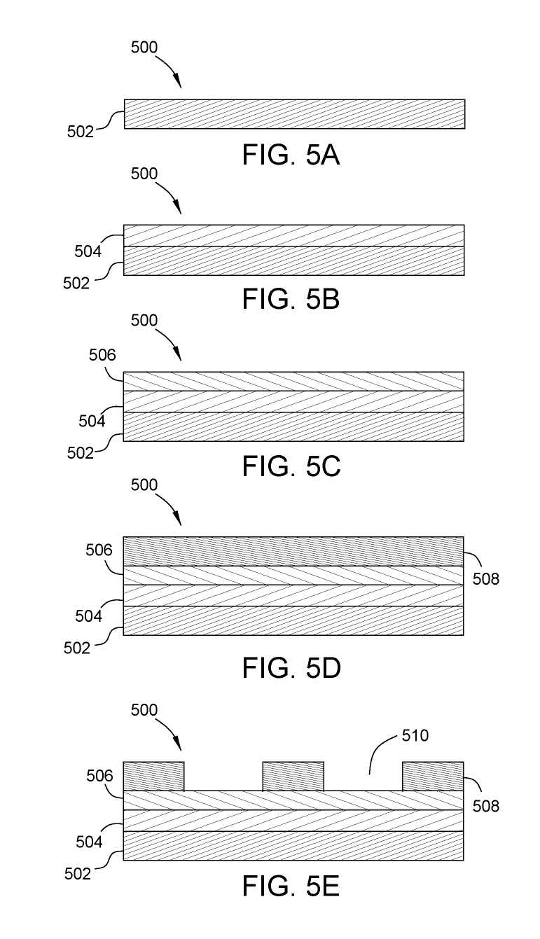

The process chamber 100, the process chamber 200 and the platforms 300 and 350 may be used to perform the methods described in FIG. 4 and FIG. 5A-5E below. In some process flows, it may be desirable for the substrate to be further processed in the platforms 300 and/or 350, or more typically be processed in a separate platform that is configured similarly to the platform shown in FIGS. 3A and/or 3B.

FIG. 4 is a block diagram of a method of depositing a hardmask layer and/or an ARC, according to one implementation. The method 400 can include delivering a first SiOC precursor to a substrate, the substrate positioned in the processing region of a processing chamber, at 402; under a plasma using a first oxygen-containing gas being delivered at a carbon preserving flow rate, at 404; delivering the first activated oxygen plasma to the first SiOC precursor, the first activated oxygen plasma reacting with the first SiOC precursor to deposit a hardmask on the exposed surface of the substrate, at 406; delivering a second SiOC precursor to the substrate, at 408; forming a plasma using a second oxygen-containing gas creating an second activated oxygen plasma mixture, the second activated oxygen plasma being delivered at a carbon depleting flow rate, at 410; and delivering the second activated oxygen precursor to the second SiOC precursor, the second activated oxygen precursor reacting with the second SiOC precursor to deposit an anti-reflective coating on the exposed surface of the substrate, the anti-reflective coating being substantially free of carbon, at 412.

The method 400 can be used to deposit a hardmask and ARC stack over a substrate, as shown in FIGS. 5A-5E. The hardmask and the ARC are deposited sequentially, which can include intervening layers if desired. The ARC deposited by the methods described herein shows superior adhesion over other methods known in the art. Further, the hardmask and the ARC can be deposited using a single precursor and/or in the same chamber. As such, this deposition method described here can reduce costs and operating time, while providing the same or superior results, such as for a photolithography process.

The method 400 begins with delivering a first SIOC precursor to a substrate, the substrate positioned in the processing region of a processing chamber, at 402. The substrate described here, may be the same as a substrate 502 for the formation of a device 500, shown in FIG. 5A. The substrate 502 can be a substrate used for production of semiconductor devices. The substrate 502 can be silicon, germanium, glass, quartz, sapphire, or others. Further, the substrate 502 may be of a variety of shapes, such as circular, square, rectangular, or others. In one implementation, the substrate 502 is a 300 mm diameter silicon wafer. The substrate 502 described here may have one or more layers formed thereon (not shown). For the purposes of this application, these layers are considered to be part of the substrate 502.

The first SiOC precursor can include organosiloxane compounds wherein each Si atom is bonded to at least one or more carbon atoms, and each Si must include alkoxy group such as —O—R where R could be alkyl e.g. R=—(CH₂)ₙ—CH₃) or alkene groups such as —CH═CH—R or —(CH═CH)ₙ—R—(CH═CH)ₙ or even alkyne such as —C≡C—, or —(C≡C)ₙ—R—. When an organosiloxane compound includes two or more Si atoms, each Si is separated from another Si by —O—, —C—, —CH═CH—, or —C≡C—, wherein each bridging C is included in an organo group, preferably alkyl or alkenyl groups such as —CH₂—, —CH₂—CH₂—, —CH(CH₃)—, —C(CH₃)₂—. The organosiloxane compounds can be gases or liquids near room temperature and can be volatilized above about 10 Torr. Suitable SiOC precursors include:
Methylsilane
Dimethylsilane
Trimethylsilane
TriDiethoxymethylsilane,
Bis(triethoxysilyl)methane,
Bis(methyldimethoxysilyl)methane,
1,3,5-trimethyl-1,3,5-triethoxy-1,3,5-trisilacyclohexane, and
Octamethylcyclotetrasiloxane (OMCTS).

A combination of two or more of the organosiloxanes can be employed to provide a blend of desired properties such as dielectric constant, oxide content, hydrophobicity, film stress, and plasma etching characteristics.

The deposition temperature can vary between about 150 degrees Celsius and about 250 degrees Celsius. The chamber pressure can be set to a pressure of between about 2 Torr and about 15 Torr, such as from about 4.0 Torr to about 10 Torr. The SiOC precursor can be flown into the chamber with assistance of an inert carrier gas. The inert carrier gas can be a gas that is considered to be non-reactive with the substrate, the precursor or the oxygen containing gas. In one implementation, the inert carrier gas is Helium. For a 300 mm diameter substrate, the SiOC precursor flow can vary from about 350 mgm to about 750 mgm. Thus, for the SiOC precursor, the flow rate can be from about 0.005 mgm/mm² to about 0.011 mgm/mm². The inert carrier flow can vary from 2000 to 5000 sccm. Thus, for the inert carrier gas, the flow rate can be from about 0.028 sccm/mm² to about 0.071 sccm/mm².

A steady flow of the oxygen containing compound, such as O₂, (e.g., about 250 sccm to about 500 sccm) can be delivered to react with the precursor. The oxygen containing compound can be delivered at a flow rate of between 200 sccm and 800 sccm, such as from 250 sccm to about 500 sccm, for the 300 mm diameter substrate. Thus, for the O₂ in this example, the flow rate is between about 0.0028 sccm/mm² to about 0.011 sccm/mm² and from about 0.0035 sccm/mm² to about 0.007 sccm/mm², respectively. The oxygen containing compound can be delivered under the presence of from about 100 W to about 800 W, such as about 150 W to about 500 W of RF plasma. The RF plasma can be generated at a frequency of between 1 MHz and 60 MHz, such as 13.56 MHz.

Then, a plasma can be formed using a first oxygen-containing gas, creating a first activated oxygen precursor, at 404. Using Chemical vapor deposition technique the SiOC material is deposited chemical vapor deposited by reacting an oxidizable silicon, carbon and oxygen containing (SiOC) precursor comprising an oxidizable silicon, carbon and oxygen component with an oxidizing gas. The oxidizing gases include but are not limited to oxygen (O₂) or oxygen containing compounds such as nitrous oxide (N₂O), ozone (O₃), and carbon dioxide (CO₂), such as N₂O or O₂.

Then, the first activated oxygen precursor can be delivered to the first SiOC precursor, the first activated oxygen precursor reacting with the first SiOC precursor to deposit a hardmask 504 on the exposed surface of the substrate, at 406. The hardmask 504 is depicted in FIG. 5B, deposited on an exposed surface of the substrate 502. The oxygen containing precursor can be used to react or crosslink the SiOC precursor. This reaction occurs in part by displacing carbon atoms in the SiOC precursor.

The first oxygen containing precursor can be delivered at a carbon preserving flow rate. A carbon preserving flow rate is defined as a flow rate at which some carbon is preserved from the SiOC precursor. In one example, the first oxygen containing precursor is O₂. This may be a flow rate at which the carbon content of the SiOC precursor is stoichiometrically greater than the activated oxygen content of the oxygen containing precursor as delivered to the chamber. The O₂ is delivered to the SiOC precursor in the presence of the substrate 502 at a flow rate of above about 800 sccm, such as a flow rate between 1000 sccm and about 2000 sccm, as determined for the 300 mm substrate. Thus, for the O₂ in this example, the flow rate is above about 0.011 sccm/mm², such as between about 0.014 sccm/mm² and about 0.028 sccm/mm².

Oxygen and oxygen containing compounds can be dissociated to increase reactivity when necessary to achieve a desired carbon content in the deposited film. RF power can be coupled to the deposition chamber to increase dissociation of the oxidizing compounds. The oxidizing compounds may also be dissociated by RF or microwave power prior to entering the deposition chamber to reduce excessive dissociation of the SIOC precursor. Deposition of the hardmask (SiOC) or the ARC (SiO) layer can be continuous or discontinuous. Deposition can occur in a single deposition chamber or the layer can be deposited sequentially in two or more deposition chambers. Furthermore, RF power can be cycled or pulsed to reduce heating of the substrate and promote greater porosity in the deposited film.

Then, a second SiOC precursor is delivered to the substrate, at 408. The second SIOC precursor may be the same as the first SIOC precursor. Further, the second SIOC precursor can be an alkoxy silane precursor which is different from the first SIOC precursor. The second SIOC precursor can then be delivered to the hardmask layer at flow rates described above.

A plasma can then be formed using a second oxygen-containing precursor, creating a second activated oxygen precursor, at 410. The second oxygen-containing precursor can be substantially similar to the first oxygen-containing precursor described above. Further, the second oxygen-containing precursor may be a precursor selected from the precursors described with reference to the first oxygen-containing precursor, without being the same one used for the first oxygen-containing precursor. Flow rates, power source, power levels and other parameters may be substantially similar to the ones described with reference to the first oxygen-containing precursor.

The second activated oxygen precursor can then be delivered to the second SiOC precursor, the second activated oxygen precursor reacting with the second SiOC precursor to deposit an ARC on the exposed surface of the substrate, the anti-reflective coating being substantially free of carbon, at 412. The activated oxygen species from the second activated oxygen precursor then react with the SIOC precursor to form the ARC over the hardmask. The ARC described herein is depicted as ARC 506 of FIG. 5C. The activated oxygen species, being delivered carbon depleting flow rate, removes available carbon from the second SIOC precursor prior to creating a deposition product or during the deposition process. This leaves a substantially carbon free ARC layer formed over the hardmask.

The second activated oxygen precursor can be delivered at a carbon depleting flow rate. A carbon depleting flow rate is defined as a flow rate at which no measurable carbon is preserved from the SiOC precursor in the deposited layer. This may be a flow rate at which the carbon content of the SiOC precursor is stoichiometrically exceeded by the activated oxygen content of the oxygen containing precursor as delivered to the chamber. In one example, the first oxygen containing precursor is O₂. The O₂ is delivered to the SIOC precursor in the presence of the substrate 502 at a flow rate of between about 200 sccm and about 800 sccm, as determined for a 300 mm substrate. Thus, for the O₂ in this example, the flow rate is from about 0.0028 sccm/mm² to about 0.011 sccm/mm².

Once the hardmask 504 and the ARC 506 are deposited on the substrate 502, a photoresist 508 may be deposited over the stack, as shown in FIG. 5D. The photoresist receives radiation in the form of a pattern, which can be subsequently etched to form one or more reliefs 510, as shown in FIG. 5E. The reliefs 510 serve as a template for etching the ARC 506, the hardmask 504 and other portions of the substrate or layers formed thereon.

Described herein are methods of depositing SiOC and SiO layers. The SiOC layers and SiO layers may be used in the formation of semiconductor devices, such as hardmasks and ARC for use in photolithography. In same PECVD deposition chamber both the hardmask and the ARC can be deposited. The etch and ash rework performance of this alkoxysilane based ARC film was found to be better than conventional TEOS based oxide films. Thus, the resulting layers provide better properties while reduce costs and deposition time per substrate.

Carbon concentration can also be modulated using carbon containing precursors, in addition to the SiOC precursor. By using carbon containing precursors containing high carbon content can be used to incorporate more carbon in the SiOC film. Examples of such second carbon rich precursors can be Methane (CH₄), Ethane (CH₂═CH₂), Acetylene (CH≡CH) or hydrocarbon such as a: 4-Methyl-1-(1-methylethyl)-1,3-cyclohexadiene and Bicyclo [2.2.1]-hepta-2,5-diene.

While the foregoing is directed to implementations of the present disclosure, other and further implementations of the disclosure may be devised without departing from the basic scope thereof, and the scope thereof is determined by the claims that follow.

1. A method of forming a layer, comprising:
delivering a first deposition gas to a substrate in a process chamber, the first deposition gas comprising an SiOC precursor and a first flow rate of an oxygen-containing precursor;
activating the first deposition gas using a plasma, the first deposition gas forming a hardmask comprising an SiOC containing layer over an exposed surface of the substrate;
delivering a second deposition gas to the SiOC containing layer, the second deposition gas comprising an SiO precursor and a second flow rate of the oxygen containing precursor, the second flow rate being higher than the first flow rate; and
activating the second deposition gas using a plasma, the second deposition gas forming an SiO containing layer over the hardmask, the SiO containing layer being free of carbon.

2. The method of claim 1, wherein each of the SiOC precursor and the SiO precursor is an alkoxysilane precursor.

3. The method of claim 2, wherein the alkoxysilane precursor is diethoxymethylsilane or bis(triethoxysilyl)methane.

4. The method of claim 1, wherein the first flow rate is between about 0.0028 sccm/mm² to about 0.011 sccm/mm².

5. The method of claim 4, wherein the second flow rate is between about 0.014 sccm/mm² and about 0.028 sccm/mm².

6. The method of claim 1, wherein the oxygen-containing precursor is selected from the group consisting of oxygen (O₂), nitrous oxide (N₂O), ozone (O₃), carbon dioxide (CO₂), and combinations thereof.

7. The method of claim 1, wherein the first deposition gas and the second deposition gas are activated in the presence of RF power at about 150 W to about 500 W.

8. The method of claim 1, wherein the first deposition gas and the second deposition gas are activated in a remote plasma source.

9. The method of claim 1, wherein the SiOC containing layer and the SiO containing layer are deposited in the same chamber.

10. A method of forming a layer, comprising:
delivering an SiOC precursor to a substrate, the substrate positioned in the processing region of a process chamber;
forming a plasma using a first oxygen-containing precursor creating a first activated oxygen precursor, the first oxygen containing precursor being delivered at a carbon preserving flow rate;
delivering the first activated oxygen precursor to the SiOC precursor, the first activated oxygen precursor reacting with the SiOC precursor to deposit a silicon oxycarbide (SiOC) hardmask on the exposed surface of the substrate;
delivering an SiO precursor to the hardmask deposited on the substrate;
forming a plasma using a second oxygen-containing precursor creating a second activated oxygen precursor, the second activated oxygen precursor being delivered at a carbon depleting flow rate; and
delivering the second activated oxygen precursor to the SiO precursor, the second activated oxygen precursor reacting with the SiO precursor to deposit an anti-reflective coating on the hardmask, the anti-reflective coating being free of carbon.

11. The method of claim 10, wherein the SiOC precursor is an alkoxysilane precursor and the SiO precursor is an alkoxysilane precursor.

12. The method of claim 11, wherein the SiOC precursor is diethoxymethylsilane or bis(triethoxysilyl)methane and the SiO precursor is diethoxymethylsilane or bis(triethoxysilyl)methane.

13. The method of claim 10, wherein the hardmask is a silicon oxycarbide (SiOC) hardmask.

14. The method of claim 10, wherein the carbon preserving flow rate is between about 0.0028 sccm/mm² to about 0.011 sccm/mm².

15. The method of claim 14, wherein the carbon depleting flow rate is between about 0.014 sccm/mm² and about 0.028 sccm/mm².

16. The method of claim 10, wherein the first oxygen-containing precursor and the second oxygen-containing precursor are selected from the group consisting of oxygen (O₂), nitrous oxide (N₂O), ozone (O₃), carbon dioxide (CO₂), and combinations thereof.

17. The method of claim 10, wherein the first oxygen-containing precursor and the second oxygen-containing precursor are activated in the presence of RF power at about 150 W to about 500 W.

18. The method of claim 10, wherein the first oxygen-containing precursor and the second oxygen-containing precursor are activated in a remote plasma source.

19. A method of forming a layer, comprising:
delivering an SiOC precursor to a 300 mm substrate, the SiOC precursor comprising diethoxymethylsilane or bis(triethoxysilyl)methane, the substrate positioned in the processing region of a process chamber;
forming a plasma in the presence of an O₂ gas creating an activated O₂ gas, the activated O₂ gas delivered at a flow rate of between 200 sccm and 800 sccm;
delivering the activated O₂ gas to the SiOC precursor, the activated O₂ gas reacting with the SiOC precursor to deposit a silicon oxycarbide (SiOC) hardmask on the exposed surface of the substrate;
delivering an SiO precursor to the SiOC hardmask formed on the substrate; and
delivering the activated O₂ gas precursor to the SiO precursor at a flow rate greater than 1000 sccm, the activated O₂ gas reacting with the SiO precursor to deposit an anti-reflective coating on the hardmask, the anti-reflective coating being free of carbon.

20. The method of claim 19, wherein the anti-reflective coating comprises SiO₂.
